(19) United States
(12) Patent Application Publication
(10) Pub. No.: US 2011/0079769 A1
(43) Pub. Date: Apr. 7, 2011

(54) Nanometric MOS Transistor With Maximized Ration Between On-State Current and Off-State Current

(76) Inventor: Nicolas Cavassilas, Marseille (FR)

(21) Appl. No.: 11/885,900

(22) PCT Filed: Mar. 7, 2006
(86) PCT No.: PCT/FR2006/050200

§ 371 Date: Aug. 19, 2008

(30) Foreign Application Priority Data
Mar. 8, 2005 (FR) 0550605

(51) Int. Cl. H01L 29/775; B82Y 99/00

(52) U.S. Cl. 257/24; 257/E29.245; 977/938; 977/762

(57) ABSTRACT

A MOS transistor having a gate length shorter than twice the de Broglie wavelength of the charge carriers in the channel material, wherein the cross-sectional area of the channel region is decreased in the vicinity of the drain region along at least one dimension to a value smaller than half said wavelength.

### FIELD OF THE INVENTION

The present invention relates to MOS transistors of very small dimensions, currently designated as nanometric transistors.

### DISCUSSION OF THE RELATED ART

In a nanometric transistor, due to the very short gate length, quantum effects, and especially the transfer of charge carriers between the source and the drain by tunnel effect, become significant. Such quantum effects become preponderating when the gate length of the MOS transistor is on the order of magnitude of the de Broglie wavelength of the charge carriers in the channel material, for example shorter than twice this wavelength, and more specifically equal to or even much shorter than this wavelength. As an example, for an electron having an impulse resulting from the thermal agitation, the de Broglie wavelength in silicon is on the order of 14 nm at ambient temperature, and 27 nm at the temperature of liquid nitrogen (77° K). This wavelength is on the order of 25 nm in GaAs at ambient temperature.

FIG. 1 very generally shows an N-channel MOS transistor. The gate, source, and drain connections are not shown. This drawing is essentially given to set the notations which will be used in the present description. The MOS transistor is formed in a thin semiconductor material formed on an insulating layer 1. Insulating layer 1 forms a solid insulating substrate or is an insulating layer deposited on another material, for example, silicon oxide on silicon. The thin semiconductor material layer comprises a lightly-doped P-type channel region 3 formed under a gate insulator 4 and a gate conductor 5. On either side of the channel region are formed heavily-doped N-type regions 7 and 8, respectively corresponding to the source and to the drain. Such a transistor in which gate length L is, as indicated previously, on the order of the de Broglie wavelength, that is, ranges between a value of approximately twice this wavelength and values much smaller than this wavelength in the considered material, is considered.

In such a transistor, when the gate is biased for the transistor to be in the off state, charge carriers are still likely to transit from the source to the drain by tunnel effect. In other words, due to the indeterminacy principle, there is a probability for carriers considered as being in the source to be present in the drain. As a result, in such nanometric transistors, ratio I_{ON}/I_{OFF} between the on-state current (ON) and the off-state current (OFF) is much smaller than for MOS transistors of greater dimensions.

An object of the present invention is to improve this I_{ON}/T_{OFF} ratio without deteriorating other features of the transistor, and especially current I_{ON}.

### SUMMARY OF THE INVENTION

To achieve this object, the present invention provides a MOS transistor having a gate length shorter than twice the de Broglie wavelength of the charge carriers in the channel material. The cross-sectional area of the channel region is decreased in the vicinity of the drain region along at least one dimension to a value smaller than half said wavelength.

According to an embodiment of the present invention, the channel region, at least, is comprised between two insulators.

According to an embodiment of the present invention, the transistor is formed of a thin semiconductor layer formed on an insulator.

According to an embodiment of the present invention, the transistor is formed as concerns its semiconductor portion of a wire or a nanotube.

According to an embodiment of the present invention, the transistor is formed in a semiconductor bridge.

According to an embodiment of the present invention, the gate length is shorter than the de Broglie wavelength.

According to an embodiment of the present invention, the transistor is formed in a thin silicon layer, the gate length being shorter than 20 nm, and the thickness of the silicon layer at the level of the narrowing being shorter than 3 nm.

According to an embodiment of the present invention, the gate length is shorter than 10 nm.

### BRIEF DESCRIPTION OF THE DRAWINGS

The foregoing object, features, and advantages of the present invention will be discussed in detail in the following non-limiting description of specific embodiments in connection with the accompanying drawings, in which:

FIG. 1 shows a nanometric MOS transistor according to prior art;

FIG. 2 shows a nanometric MOS transistor according to an embodiment of the present invention; and

FIG. 3 shows the potential barrier between the source and the drain, in the ON state and in the OFF state, according to the present invention and according to prior art.

As usual in the representation of integrated circuits, the various drawings are not to scale.

### DETAILED DESCRIPTION

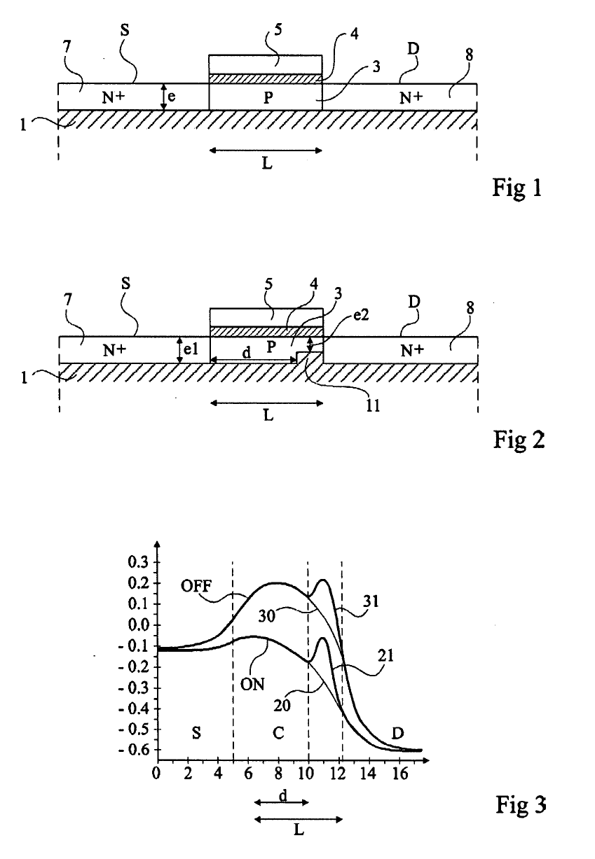

In FIG. 2, an embodiment of the present invention is shown, using the same reference numerals as in FIG. 1 to designate identical or similar elements. The thickness of the thin semiconductor layer comprising source, channel, and drain regions 7, 3, and 8 is designated as e1. According to the present invention, channel region 3 comprises a narrowing in the vicinity of drain region 8, the channel layer then only having a thickness e2 at the level of this narrowing. This narrowing for example results from a protrusion 11 of insulating layer 1 in the channel region portion close to the drain region. This narrowing results in increasing the quantum confinement of the electrons in the channel in the vicinity of the drain and in creating an additional potential barrier. Of course, for this effect to be significant, thickness e2 at the level of the narrowing must be small enough for the charge carriers to be confined. Typically, thickness e2 must be smaller than half the de Broglie wavelength.

Simulations performed by the present inventor show that this narrowing results in a substantially unmodified on-state current with respect to that of the transistor of FIG. 1, while the off-state current is clearly decreased.

FIG. 3 enables understanding the effect of the narrowing. This drawing shows in ordinates the potential energy in electronvolts as seen by an electron in the channel region and in the vicinity thereof in the source and the drain. The abscissas show distances in nanometers. In this drawing, the source is located between values 0 and 5 nm, the channel is located between 5 and 12 nm, and the drain is located between 12 and 17 nm. The lower curve (ON) shows the potential energy in the on state with a curve 20 for the transistor of FIG. 1 and with a curve 21 for the transistor of FIG. 2. The lower curve (OFF) shows the potential energy in the off state with a curve 30 for the transistor of FIG. 1 and with a curve 31 for the transistor of FIG. 2. It can be seen that the effect of the narrowing arranged at a distance d, on the order of 4 nm, from the source, is to create an additional potential barrier in the channel region in the vicinity of the drain. In the ON state, in which the general barrier between the source and the drain is of relatively low height, and in which the electrons mainly pass by thermionic effect, the presence of this small additional barrier practically does not change current I_{ON}. In certain cases, an increase in current I_{ON} presumably due to coupling effects between energy sub-bands has even been observed. In the OFF state where the potential barrier is highest, this barrier normally prevents the propagation of the greater part of the thermionic current and the current is essentially a quantum current, that is, a tunnel-effect current, the presence of the additional barrier causing a significant decrease in the tunnel-effect propagation.

Although a specific embodiment of the present invention has been described previously, it should be noted that this embodiment has been described as an illustration only and that the present invention is likely to have many variations. Generally, the present invention applies to a MOS transistor comprising a confined channel region and provides a narrowing of its channel region in the vicinity of the drain. The MOS transistor may be a dual-gate transistor, that is, another gate may be placed on the lower surface side. In this case, the narrowing may result from protrusions on the lower surface side and/or on the upper surface side. The transistor may also be formed of a wire or nanotube surrounded at the level of its channel region with a gate insulator, the shape of the narrowing being then determined according to a possible anisotropy of the considered semiconductor material. Silicon-on-nothing MOS transistors SON may also be used. Of course, the present invention is not limited to the use of silicon as a semiconductor element. SiGe-type semiconductors and III-V semiconductors such as gallium arsenide may especially be used. Similarly, the present invention applies to N-channel MOS transistors as well as to P-channel MOS transistors of enrichment or depletion type. More generally, the various nanometric MOS transistor structure and forming variations may be used within the context of the present invention.

1. A MOS transistor having a gate length shorter than twice the de Broglie wavelength of the charge carriers in the channel material, wherein the cross-sectional area of the channel region is decreased in the vicinity of the drain region along at least one dimension to a value smaller than half said wavelength.

2. The transistor of claim 1, wherein the channel region, at least, is comprised between two insulators.

3. The transistor of claim 1, wherein the transistor is formed of a thin semiconductor layer formed on an insulator.

4. The transistor of claim 1, formed, as concerns its semiconductor portion, of a wire or a nanotube.

5. The transistor of claim 1, formed in a semiconductor bridge.

6. The transistor of claim 1, wherein the gate length is shorter than the de Broglie wavelength.

7. The transistor of claim 1, formed in a thin silicon layer, the gate length being shorter than 20 nm, and the thickness of the silicon layer at the level of the narrowing being shorter than 3 nm.

8. The transistor of claim 7, wherein the gate length is shorter than 10 nm.
